(19) United States
(12) Patent Application Publication
(10) Pub. No.: US 2026/0227577 A1
(43) Pub. Date: Aug. 6, 2026

(54) ON-CHIP ALL-OPTICAL SWITCHING NETWORK APPARATUS, SEMICONDUCTOR DEVICE, AND METHOD FOR MANUFACTURING THE SAME

(71) Applicant: HANGZHOU GUANGZHIYUAN TECHNOLOGY CO., LTD., Hangzhou City (CN)

(72) Inventors: Yichen SHEN, Hangzhou City (CN); Huaiyu MENG, Hangzhou City (CN); Yelong XU, Hangzhou City (CN)

(21) Appl. No.: 19/630,831

(22) Filed: Mar. 27, 2026

Related U.S. Application Data
(63) Continuation of application No. PCT/CN2024/118412, filed on Sep. 12, 2024.

(30) Foreign Application Priority Data
Sep. 28, 2023 (CN) 202311287540.8

(51) Int. Cl. G02B 6/35

(52) U.S. Cl. CPC G02B 6/3598

(57) ABSTRACT

An on-chip all-optical switching network apparatus, a semiconductor device, and a manufacturing method thereof are provided. The apparatus includes a photonic chip on which at least two optically interconnected photonic integrated circuit sub-chips are formed, and at least two optical switching control analog electrical chips respectively disposed on the photonic integrated circuit sub-chips. Each photonic integrated circuit sub-chip includes at least one on-chip optical switch, at least two communication nodes configured to communicate with external devices, and a plurality of first-type optical waveguides configured to connect the on-chip optical switch with the communication nodes. Any two of the communication nodes on the photonic chip are configured to communicate with each other via at least one of the on-chip optical switches.

### CROSS-REFERENCE TO RELATED APPLICATION(S)

This application claims priority to Chinese Patent Application No. 202311287540.8, filed on Sep. 28, 2023, and entitled “On-Chip All-Optical Switching Network Apparatus, Semiconductor Device, and Method for Manufacturing the Same,” the entire disclosure of which is incorporated herein by reference.

### FIELD OF THE INVENTION

The present disclosure relates to the field of semiconductor technology, and more particularly to an on-chip all-optical switching network apparatus, a semiconductor device, and a method for manufacturing the same.

### BACKGROUND OF THE INVENTION

Very-large-scale integration (VLSI) technology has become a fundamental enabler for the evolution of information-based society. Various types of chips widely used in information systems typically rely on continuous advancements in electrical semiconductor manufacturing processes to improve performance and optimize power consumption. However, as electrical semiconductor processes gradually approach their physical limits, the pace of Moore's Law has slowed, and the cost of manufacturing large-scale chips using advanced processes has increased significantly.

The rapid development of new artificial intelligence (AI) applications such as the newly emerging ChatGPT and other artificial intelligence generated content (AI Generated Content, AIGC) places increasingly higher requirements on the computing power of computing systems. In addition, as the overall chip area increases, the latency and energy consumption associated with data movement within and between chips also increase correspondingly.

Conventional information interconnection is primarily implemented through electronic signal transmission through copper-based interconnects. However, the transmission speed and distance of electrical signals are limited by resistance-capacitance (RC) time constants and electrical losses. As a result, the cross-sectional area of required copper interconnects must increase significantly to support higher transmission speed and longer transmission distance. In addition, signal crosstalk between adjacent electrical interconnect channels further constrains the achievable power efficiency and bandwidth density. Consequently, the power consumption and bandwidth density limitations of chip-to-chip electrical interconnects have become major bottlenecks in the development of high-performance chip systems. Moreover, conventional electrical interconnect interfaces are sensitive to interconnect distance, thereby restricting the interconnection architectures among digital semiconductor chips. In point-to-point interconnection networks, each serializer/deserializer (SerDes) interface is typically required to communicate with a dedicated processing unit, such as an XPU used in artificial intelligence computing systems, which limits the available bandwidth between pairs of processing units.

### SUMMARY OF THE INVENTION

In view of the foregoing drawbacks of electronic information transmission, the present disclosure provides an on-chip all-optical switching network apparatus, a semiconductor device, and a method for manufacturing the same.

According to a first aspect of the present disclosure, an on-chip all-optical switching network apparatus is provided, comprising:
a photonic chip in which at least two photonic integrated circuit (PIC) sub-chips are formed, wherein adjacent PIC sub-chips are optically interconnected with each other; and
at least two optical switching control analog electrical chips respectively disposed on the at least two PIC sub-chips;
wherein each PIC sub-chip comprises at least one on-chip optical switch, at least two communication nodes configured to communicate with external devices, and a plurality of first-type optical waveguides configured to connect the at least one on-chip optical switch with the communication nodes, wherein each on-chip optical switch is arranged in a one-to-one correspondence with a respective one of the at least two optical switching control analog electrical chips; and
wherein, on the photonic chip, any two of the communication nodes are configured to communicate with each other via the at least one on-chip optical switch.

On each PIC sub-chip, the optical switching control analog electrical chip is disposed above the on-chip optical switch so as to control the on-chip optical switch.

In some embodiments, each communication node comprises at least two electronic-photonic conversion units and at least two photonic-electronic conversion units. The at least two electronic-photonic conversion units are optically connected to at least two on-chip optical switches via respective first-type optical waveguides, and the at least two photonic-electronic conversion units are optically connected to output ports of the at least two on-chip optical switches via respective first-type optical waveguides.

In some embodiments, for each communication node, a number of the electronic-photonic conversion units is equal to that of the photonic-electronic conversion units, and each is equal to a total number of on-chip optical switches on the photonic chip.

In some embodiments, each on-chip optical switch includes a plurality of input ports and a plurality of output ports. A number of the input ports and a number of the output ports of each on-chip optical switch are equal to a total number of the communication nodes on the photonic chip.

In some embodiments, the plurality of input ports of each on-chip optical switch are respectively optically connected to at least one electronic-photonic conversion unit in each communication node via different first-type optical waveguides, and the plurality of output ports of each on-chip optical switch are respectively optically connected to at least one photonic-electronic conversion unit in each communication node via different first-type optical waveguides.

In some embodiments, the on-chip all-optical switching network is configured such that an optical path between any two communication nodes includes at least one on-chip optical switch.

In some embodiments, each electronic-photonic conversion unit comprises a modulator, and/or each photonic-electronic conversion unit comprises a detector. In some embodiments, the at least two electronic-photonic conversion units comprise a modulator array, and/or the at least two photonic-electronic conversion units comprise a detector array.

In some embodiments, within each communication node, the modulators and the detectors are arranged side by side or arranged alternately.

In some embodiments, the modulator comprises a micro-ring modulator, a Mach-Zehnder modulator, or an electro-absorption modulator. In some embodiments, the detector comprises a micro-ring detector or a photodiode.

In some embodiments, each PIC sub-chip further comprises an optical input coupler and an optical power splitter.

The optical input coupler on one of the PIC sub-chips is configured to couple light from an off-chip light source into the photonic chip. The optical power splitter is optically connected to the optical input coupler via another first-type optical waveguide, and is configured to split the coupled light from the optical input coupler into a plurality of optical outputs having substantially identical power, the plurality of optical outputs being transmitted to the respective modulators.

In some embodiments, the optical input coupler comprises a grating coupler or an edge coupler.

In some embodiments, in the photonic chip, first-type optical waveguides of two adjacent PIC sub-chips are optically interconnected.

In some embodiments, first-type optical waveguides facing each other at a junction between two adjacent PIC sub-chips are configured such that the waveguide cross-section gradually increases from one PIC sub-chip toward the other PIC sub-chip, thereby facilitating optical alignment at the junction.

In some embodiments, each PIC sub-chip further comprises second-type optical waveguides disposed in a different layer from the first-type optical waveguides. One or more of the at least one on-chip optical switch, the at least two electronic-photonic conversion units, the at least two photonic-electronic conversion units, the optical input coupler, and the optical power splitter are optically connected to corresponding first-type optical waveguides via respective second-type optical waveguides, and the second-type optical waveguides are optically coupled to the first-type optical waveguides via evanescent-wave couplers.

In some embodiments, the first-type optical waveguides comprise silicon nitride waveguides. In some embodiments, the second-type optical waveguides comprise silicon waveguides.

In some embodiments, the on-chip optical switch is a silicon photonic switch including a plurality of optical switching units, and each optical switching control analog electrical chip is configured to control the plurality of optical switching units to perform data scheduling and switching in the on-chip all-optical switching network.

In some embodiments, the at least one on-chip optical switch and the at least two communication nodes are disposed in the same layer. In some embodiments, each optical switching unit comprises a Mach-Zehnder interferometer structure.

In some embodiments, the PIC sub-chips are fabricated by exposure using a full-reticle mask.

According to a second aspect of the present disclosure, a semiconductor device is provided, comprising:
the on-chip all-optical switching network apparatus according to any embodiment of the first aspect;
a plurality of analog electrical chips connected to the on-chip all-optical switching network apparatus and configured such that any two of the plurality of analog electrical chips communicate with each other via at least one on-chip optical switch of the on-chip all-optical switching network apparatus; and
a plurality of digital electrical chips, each digital electrical chip being electrically connected to a respective analog electrical chip, such that any two of the plurality of digital electrical chips communicate with each other via at least two of the analog electrical chips and the at least one on-chip optical switch.

In some embodiments, an information transmission path between any two analog electrical chips includes at least one on-chip optical switch.

In some embodiments, an information transmission path between any two digital electrical chips includes at least one optical path, the optical path including at least one on-chip optical switch.

In some embodiments, the semiconductor device further comprises a substrate. The photonic chip is mounted on the substrate, the plurality of analog electrical chips are respectively mounted on corresponding photonic integrated circuit sub-chips of the photonic chip, and the digital electrical chips corresponding to the respective analog electrical chips are respectively mounted on the substrate.

In some embodiments, on each PIC sub-chip, the analog electrical chips and the communication nodes are arranged in a one-to-one correspondence, and each analog electrical chip is disposed above the corresponding communication node.

According to a third aspect of the present disclosure, a method for manufacturing the on-chip all-optical switching network apparatus according to the first aspect is provided, comprising:
providing a photonic chip in which at least two photonic integrated circuit sub-chips are formed, adjacent photonic integrated circuit sub-chips being optically interconnected with each other; and
providing at least two optical switching control analog electrical chips and respectively disposing the optical switching control analog electrical chips on the at least two photonic integrated circuit sub-chips;
wherein each photonic integrated circuit sub-chip comprises at least one on-chip optical switch, at least two communication nodes configured to communicate with external devices, and a plurality of first-type optical waveguides configured to the at least one on-chip optical switch with the at least two communication nodes, and wherein each on-chip optical switch is arranged in a one-to-one correspondence with a respective one of the at least two optical switching control analog electrical chips; and
wherein, on each photonic integrated circuit sub-chip, any two communication nodes are configured to communicate with each other via the at least one on-chip optical switch.

In some embodiments, the photonic integrated circuit sub-chips are fabricated by exposure using a full-reticle mask.

According to a fourth aspect of the present disclosure, a method for manufacturing a semiconductor device according to the second aspect is provided, comprising:
providing the on-chip all-optical switching network apparatus according to the first aspect;
providing a plurality of analog electrical chips and connecting the plurality of analog electrical chips to the on-chip all-optical switching network apparatus such that any two of the plurality of analog electrical chips communicate with each other via at least one on-chip optical switch; and
providing a plurality of digital electrical chips and electrically connecting each digital electrical chip to a corresponding analog electrical chip such that any two of the plurality of digital electrical chips communicate with each other via at least two of the analog electrical chips and the at least one on-chip optical switch.

In some embodiments, the method for manufacturing the semiconductor device further comprises:
providing a substrate;
mounting the photonic chip on the substrate;
mounting the plurality of analog electrical chips respectively on corresponding photonic integrated circuit sub-chips of the photonic chip; and
mounting the plurality of digital electrical chips corresponding to the respective analog electrical chips on the substrate.

The present disclosure provides, among others, the following technical effects and advantages.

In some embodiments, a photonic chip is formed by optically stitching together a plurality of photonic integrated circuit sub-chips fabricated using a full-reticle mask exposure, through optical waveguides. By using the photonic chip as an interposer layer to interconnect electrical chips, power consumption and bandwidth density bottlenecks associated with conventional inter-chip interconnections can be alleviated. Within the photonic chip, the on-chip optical switches are laterally scalable. Through lateral scaling of the on-chip optical switches, an arbitrary number of digital electrical chips can perform parallel information processing concurrently, thereby better satisfying the computing capacity and bandwidth demands of artificial intelligence (AI) algorithms.

In some embodiments, by separating the analog electrical chips from the digital electrical chips, performance optimization can be independently achieved using different fabrication processes. This architecture also addresses the relatively slow product iteration cycle of analog electrical chips and further improves overall system yield.

In some embodiments, the on-chip all-optical switching network reuses a plurality of analog electrical chips and a plurality of digital electrical chips, which are interconnected via a photonic chip formed by stitching full-reticle PIC sub-chips. Except for exposure masks used for optical couplers that connect input lasers to communication nodes through silicon nitride waveguides, exposure masks for other components on the PIC sub-chips are identical, thereby reducing tape-out costs. While improving system energy efficiency, this approach overcomes reticle size limitations, effectively increases the aggregate area of digital electrical chips, and enhances the total computational throughput of the system.

Furthermore, conventional computing systems typically require long-reach SerDes interfaces and printed circuit board (PCB) traces to achieve full connectivity between chips. In contrast, the on-chip all-optical switching network enables computing chips (i.e., digital electrical chips) to be interconnected using ultra-short-reach SerDes or parallel interfaces, thereby reducing interconnect power consumption. In addition, the use of the on-chip all-optical switching network enables inter-chip interconnections to be field-reconfigurable rather than fixed point-to-point electrical links.

This reconfigurability provides multiple benefits. For example, interconnect topologies can be adapted according to the requirements of specific machine learning models. From a topology perspective, data-flow requirements of different machine learning models can generally be categorized into three types: data parallelism, in which each chip loads an entire model and different chips process different data sets; model parallelism, in which particularly large layers of a model are partitioned such that each chip performs computation on only a portion of such layers; and pipeline parallelism, in which different layers of a model are assigned to different chips and different data flows correspond to different computational interconnect topologies. By using reconfigurable optical interconnects, the present disclosure enables rapid switching among different inter-chip interconnect topologies, thereby improving bandwidth utilization and enhancing scalability of AI chips, allowing multiple chips to cooperate efficiently and reliably to accelerate large-scale models. Moreover, the entire on-chip optical switch consumes only on the order of a few hundred milliwatts of power, which is several orders of magnitude lower than that of an electrical switch.

Additionally, commercial deployment of silicon photonic switches often encounters challenges related to fiber coupling and polarization dependence. The present disclosure employs optical switches used directly on-chip (i.e., on-chip optical switches), thereby avoiding such issues. Conventional optical switches typically use optical fibers as input/output interfaces, with fiber array pitches generally being about 250 μm or 127 μm. For optical switches having tens of optical input/output ports, this configuration not only occupies a large chip area but also reduces fiber-to-chip coupling yield, exacerbating optical coupling losses. By contrast, using on-chip optical switches mitigates optical coupling loss issues.

Furthermore, conventional sub-micrometer silicon-on-insulator waveguides exhibit strong birefringence, resulting in significant differences in effective refractive indices between transverse electric (TE) and transverse magnetic (TM) polarizations, such that couplers and phase shifters based thereon are polarization dependent. Reducing polarization dependence has long been a challenge for fiber-coupled silicon photonic switches. By directly employing on-chip optical switches with fixed and single waveguide input/output polarization states, the present disclosure effectively circumvents polarization-dependence challenges associated with silicon photonic switches while providing improved stability. In addition, the on-chip optical switches are compatible with silicon photonic fabrication processes of the photonic chip, thereby simplifying process flows and reducing manufacturing costs.

Various aspects, features, and advantages of the present disclosure will be described in further detail below with reference to the accompanying drawings. The foregoing aspects, features, and advantages will become more apparent from the following detailed description in conjunction with the accompanying drawings.

### BRIEF DESCRIPTION OF THE DRAWINGS

FIG. 1 is a schematic plan view illustrating an on-chip all-optical switching network apparatus according to an embodiment of the present invention.

FIG. 2 is a schematic diagram illustrating a stitching coupler for optical waveguide interconnection between adjacent photonic integrated circuit sub-chips of FIG. 1.

FIG. 3 is a schematic diagram illustrating an evanescent-wave coupler for interconnection of optical waveguides in different layers of a photonic integrated circuit sub-chip of FIG. 1.

FIG. 4 is a schematic diagram illustrating an on-chip optical switch composed of a plurality of optical switching units.

FIG. 5 is a schematic diagram illustrating a structure of an optical switching unit shown in FIG. 4.

FIG. 6 is a schematic diagram illustrating a connection topology among four communication nodes in the on-chip all-optical switching network apparatus of FIG. 1.

FIG. 7 is a schematic plan view illustrating a semiconductor device according to an embodiment of the present invention.

FIG. 8 is a schematic diagram illustrating a packaging structure of the semiconductor device of FIG. 7.

FIG. 9 is a schematic plan view illustrating a semiconductor device according to another embodiment of the present invention.

FIG. 10 is a schematic plan view illustrating a semiconductor device according to yet another embodiment of the present invention.

### DETAILED DESCRIPTION OF THE INVENTION

Exemplary embodiments will be described in greater detail below with reference to the accompanying drawings. Certain terms are used herein for convenience of description only and are not intended to limit the scope of the present invention. For example, terms such as “top,” “bottom,” “upper,” “lower,” “above,” and “below” may be used to describe relative positions or directions with reference to the drawings. Terms such as “front,” “rear,” “back,” “side,” “outer,” and “inner” may be used to describe orientations and/or positions of components or portions thereof within a consistent but arbitrary frame of reference, which can be clearly understood from the written description in conjunction with the associated drawings. Unless expressly indicated otherwise by the context, terms such as “first,” “second,” and other similar numerical designations do not imply any order, sequence, or priority.

It should be understood that when an element or feature is described as being “on,” “connected to,” or “coupled to” another element or layer, it may be directly on, connected to, or coupled to the other element or layer, or one or more intervening elements or layers may be present. Likewise, when an element or feature is described as being “between” two elements or features, it may be the only element or feature between the two elements or features, or one or more intervening elements or features may also be present.

The terminology used herein is for the purpose of describing particular embodiments only and is not intended to limit the present invention. Such terminology includes the terms specifically used herein, their derivatives, and terms of similar meaning. As used herein, the singular forms “a,” “an,” and “the” are intended to include the plural forms as well, unless the context clearly indicates otherwise. It should also be understood that the terms “comprise,” “comprising,” “include,” “including,” “have,” and “having” specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of” preceding a list of elements modify the entire list of elements and not individual elements within the list.

As used herein, terms such as “substantially,” “approximately,” and similar expressions are used as terms of approximation rather than as terms of degree, and are intended to account for inherent variations in measured or calculated values as recognized by those of ordinary skill in the art. As used herein, the terms “use,” “using,” and “used” are interchangeable with the terms “utilize,” “utilizing,” and “utilized,” respectively.

FIG. 1 illustrates an exemplary embodiment of an on-chip all-optical switching network apparatus according to the present invention. In this exemplary embodiment, the on-chip all-optical switching network apparatus comprises a photonic chip 100, which includes photonic integrated circuit sub-chips 110 and 120 that are optically interconnected with each other. In some embodiments, the photonic chip 100 is fabricated using full-reticle exposure masks to form the photonic integrated circuit sub-chips therein, and adjacent photonic integrated circuit sub-chips are optically interconnected. Each photonic integrated circuit sub-chip comprises a plurality of first-type optical waveguides 401 and an on-chip optical switch 202.

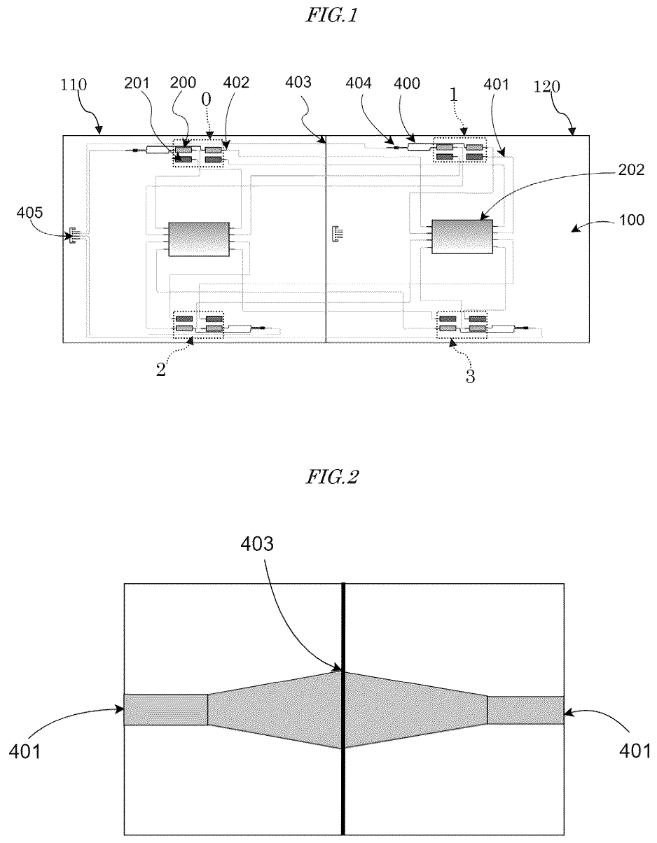

In the exemplary embodiment, optical waveguides at a junction or interface 403 between adjacent photonic integrated circuit sub-chips 110 and 120 are optically connected via a stitching coupler. The structure of the stitching coupler is illustrated in FIG. 2. By way of example, the first-type optical waveguides 401 on opposite sides of the interface 403 are configured such that a cross-sectional dimension of each waveguide gradually increases from one photonic integrated circuit sub-chip toward the other photonic integrated circuit sub-chip (e.g., in a horn-shaped or tapered configuration), thereby enlarging a coupling surface, increasing alignment tolerance between adjacent first-type optical waveguides 401 at the interface, and improving coupling efficiency. The first-type optical waveguides 401 include waveguides connecting communication nodes to the on-chip optical switch 202, as well as waveguides connecting an optical input coupler 405 to an optical power splitter 404.

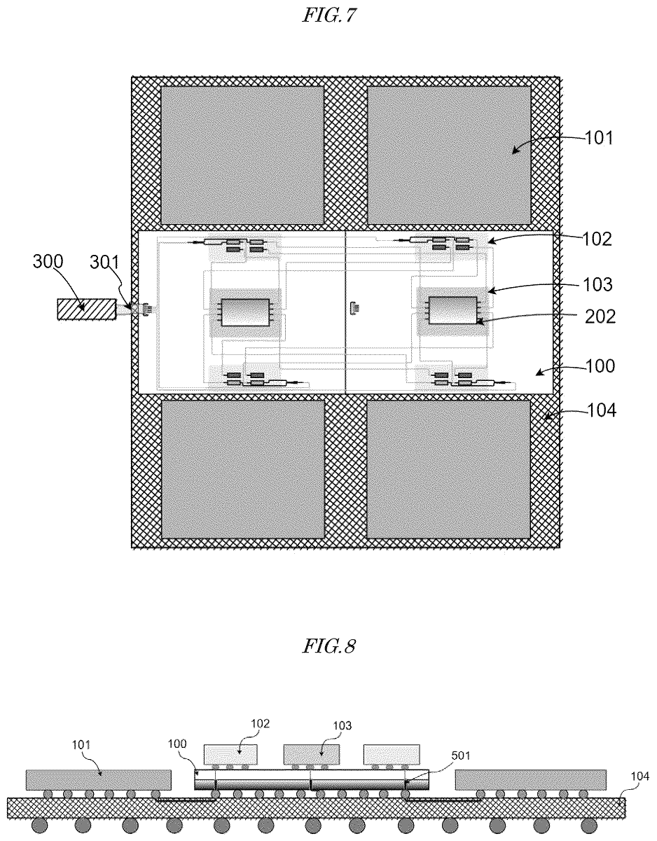

In the exemplary embodiment, as shown in FIG. 1, each photonic integrated circuit sub-chip is provided with two communication nodes. Accordingly, the photonic chip 100 includes four communication nodes, namely Node 0, Node 1, Node 2, and Node 3. Each communication node is configured to communicate with an external device, such as an analog electrical chip 102 described below. On the photonic chip 100, Node 0, Node 1, Node 2, and Node 3 are optically interconnected via a plurality of first-type optical waveguides 401 and at least one on-chip optical switch 202. The on-chip all-optical switching network apparatus further comprises an optical switching control analog electrical chip disposed on each photonic integrated circuit sub-chip (see element 103 in FIGS. 7 and 8). As shown in FIGS. 7 and 8, on the photonic chip 100, the optical switching control analog electrical chip 103 is disposed above the on-chip optical switch 202 to facilitate control of the on-chip optical switch.

In some embodiments, each communication node comprises at least two electronic-photonic conversion units and at least two photonic-electronic conversion units. The numbers of electronic-photonic conversion units and photonic-electronic conversion units in each communication node may be equal and correspond to the total number of on-chip optical switches in the photonic chip. Each on-chip optical switch includes a plurality of input ports and a plurality of output ports. The number of input ports of each on-chip optical switch is equal to the total number of communication nodes on the photonic chip, and the number of output ports of each on-chip optical switch is likewise equal to the total number of communication nodes disposed on the photonic chip. As a result, each communication node is capable of exchanging information with each on-chip optical switch.

In the exemplary embodiment, each electronic-photonic conversion unit comprises a modulator 200, and each photonic-electronic conversion unit comprises a detector 201. Two modulators 200 form a modulator array, and two detectors 201 form a detector array, with the modulators 200 and the detectors 201 arranged side by side. In alternative embodiments, the modulators and detectors may be arranged in an alternating configuration. In some embodiments, the modulator 200 may include a micro-ring modulator, a Mach-Zehnder modulator, or an electro-absorption modulator. In some embodiments, the detector 201 may include a micro-ring detector or a photodiode.

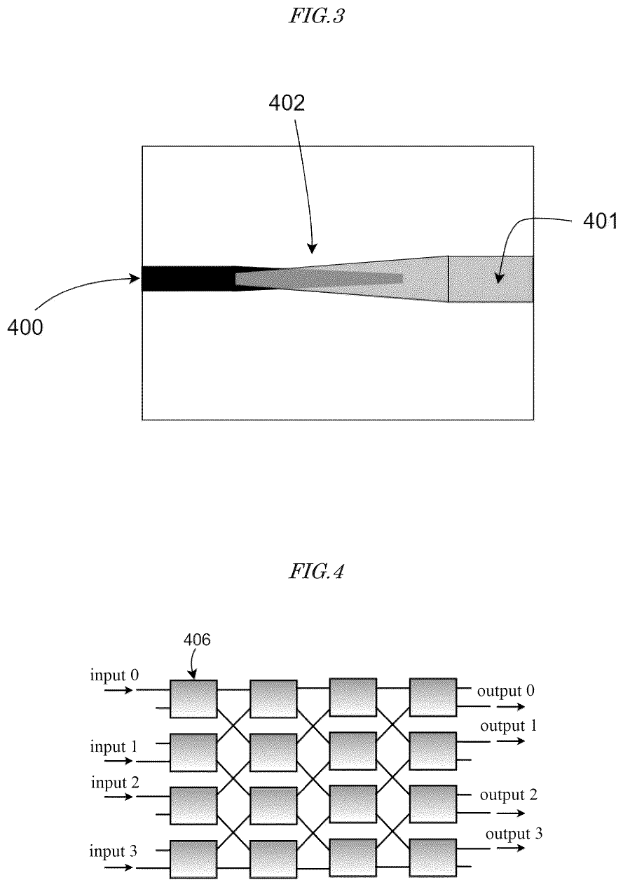

In the exemplary embodiment, the two modulators 200 are respectively optically connected to input ports of the on-chip optical switches in the photonic integrated circuit sub-chips 110 and 120 via two respective first-type optical waveguides 401. The two detectors 201 are respectively optically connected to output ports of the on-chip optical switches in the photonic integrated circuit sub-chips 110 and 120 via another two respective first-type optical waveguides 401. In the exemplary embodiment, the modulators and detectors are optically connected to the corresponding first-type optical waveguides 401 via respective second-type optical waveguides 400. Within the photonic integrated circuit sub-chip (or the photonic chip), the second-type optical waveguides 400 and the first-type optical waveguides 401 are disposed in different layers. To achieve optical coupling between waveguides disposed in different layers, as shown in FIG. 3, an evanescent-wave coupler 402 is formed between a second-type optical waveguide 400 and a first-type optical waveguide 401, thereby optically coupling the second-type optical waveguide 400 to the first-type optical waveguide 401. In the exemplary embodiment, the input ports and output ports of the on-chip optical switch are connected to corresponding first-type optical waveguides via respective second-type optical waveguides.

In an exemplary embodiment, as shown in FIG. 1, each on-chip optical switch 202 includes four input ports and four output ports. The four input ports of each on-chip optical switch 202 are respectively connected, via four first-type optical waveguides 401, to a modulator 200 of Node 0, a modulator 200 of Node 1, a modulator 200 of Node 2, and a modulator 200 of Node 3. Correspondingly, the four output ports of each on-chip optical switch 202 are respectively connected, via another four first-type optical waveguides 401, to a detector 201 of Node 0, a detector 201 of Node 1, a detector 201 of Node 2, and a detector 201 of Node 3.

The on-chip optical switch 202 comprises a plurality of optical switching units. In an exemplary embodiment, as shown in FIG. 4, the on-chip optical switch 202 is a 4×4 optical switch including sixteen optical switching units 406 arranged in a 4×4 matrix. By controlling the signal output port of each optical switching unit 406, arbitrary routing configurations between four inputs and four outputs shown in FIG. 4 can be implemented, and the insertion loss of each optical path is independent of the specific routing path selected.

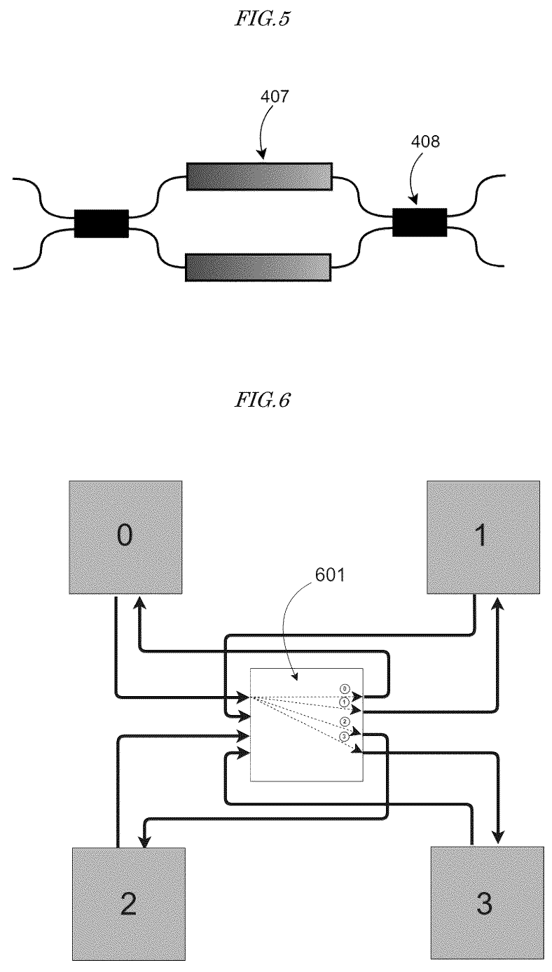

In an exemplary embodiment, as shown in FIG. 5, each optical switching unit 406 has a Mach-Zehnder interferometer structure and comprises an electronic-photonic or thermo-photonic phase shifter 407 and a 2×2 beam splitter 408. The optical switching control analog electrical chip 103, described in further detail below, is configured to control the electronic-photonic or thermo-photonic phase shifters 407 on upper and lower arms of the Mach-Zehnder interferometer so as to adjust the optical amplitude and thereby select an output port, thus enabling scheduling and switching of data transmitted in the on-chip optical switching network.

Accordingly, a connection topology among four communication nodes of the on-chip all-optical switching network apparatus formed via the on-chip optical switches 202 is illustrated in FIG. 6. Each communication node is optically interconnected, via an optical switching network 601, with the four communication nodes including itself. The optical switching network 601 enables reconfiguration of optical paths, thereby allowing real-time modification of connections between input ports and output ports. As shown in FIG. 6, for example, information transmitted from Node 0 may be selectively routed via the optical switching network 601 to Node 0, Node 1, Node 2, or Node 3.

In an exemplary embodiment, as shown in FIG. 1, each photonic integrated circuit sub-chip of the photonic chip 100 further comprises an optical input coupler 405 and an optical power splitter 404. The optical input coupler 405 of one photonic integrated circuit sub-chip (for example, the first photonic integrated circuit sub-chip or the second photonic integrated circuit sub-chip) is connected to the optical power splitter 404 via a first-type optical waveguide 401 and is configured to couple light from an off-chip light source into the photonic chip 100. The optical power splitter 404 is configured to split light received from the optical input coupler 405 into a plurality of optical outputs, each optical output having substantially equal optical power. The plurality of optical outputs are transmitted to respective modulators 200 via a plurality of second-type optical waveguides 400.

As shown in FIG. 1, light coupled into the optical input coupler 405 on the first photonic integrated circuit sub-chip is transmitted to modulators 200 on the two photonic integrated circuit sub-chips via the first-type optical waveguides 401, the second-type optical waveguides 400, or via the optical power splitter 404 followed by the second-type optical waveguides 400. The first-type optical waveguide 401 connecting the optical input coupler 405 and the optical power splitter 404 may be coupled, via an evanescent-wave coupler, to a second-type optical waveguide 400 used for optical input, and the second-type optical waveguide 400 used for optical input is connected to the modulator 200. In some embodiments, the first-type optical waveguides 401 comprise silicon nitride waveguides. In some embodiments, the second-type optical waveguides 400 comprise silicon waveguides.

In some embodiments, the optical input coupler, the optical power splitter, the modulators, the detectors, the on-chip optical switch, and the second-type optical waveguides are disposed in a same layer. An output end of the optical input coupler, input and output ends of the optical power splitter, input and output ends of the modulators, an input end of the detectors, and input and output ends of the on-chip optical switch are respectively connected to corresponding first-type optical waveguides 401 via respective second-type optical waveguides 400, wherein the second-type optical waveguides 400 are coupled to the corresponding first-type optical waveguides 401 via evanescent-wave couplers.

In some embodiments, the optical input coupler 405 comprises a grating coupler or an edge coupler. The optical power splitter 404 comprises a beam splitter.

As described above, in embodiments, a plurality of photonic integrated circuit sub-chips fabricated using a full-reticle exposure mask are optically stitched together through waveguides to form a photonic chip. The photonic chip serves as an interposer for connecting electrical chips, thereby alleviating power consumption and bandwidth density bottlenecks associated with chip-to-chip interconnections. Except for exposure masks used for forming the first-type optical waveguides connecting the optical input coupler 405 and the optical power splitter 404, the exposure masks used for other components on the photonic integrated circuit sub-chips are identical, thereby reducing fabrication and tape-out costs.

Applying the on-chip all-optical switching network apparatus of the foregoing embodiments to artificial intelligence chips can provide advantages such as improved system energy efficiency. Exemplary applications of the on-chip all-optical switching network apparatus are described below.

FIGS. 7 and 8 illustrate a semiconductor device as an exemplary application of the on-chip all-optical switching network apparatus. The on-chip all-optical switching network apparatus corresponds to any of the foregoing embodiments, and therefore reference is made to the previously described figures and reference numerals. In an exemplary embodiment, the semiconductor device comprises a plurality of digital electrical chips and a plurality of analog electrical chips connected to the on-chip all-optical switching network apparatus, wherein each digital electrical chip is electrically connected to a corresponding analog electrical chip.

In an exemplary embodiment, as shown in FIG. 7, four analog electrical chips 102 are configured such that any two analog electrical chips 102 are capable of communicating with each other via the on-chip optical switching network formed on the photonic chip 100, thereby enabling any two of the digital electrical chips to communicate with each other via at least two analog electrical chips and the on-chip optical switching network. An information transmission path between any two analog electrical chips 102 includes at least one on-chip optical switch 202. That is, communication between any two analog electrical chips 102 may be realized via a single on-chip optical switch 202 or via multiple on-chip optical switches 202. An information transmission path between any two digital electrical chips 101 includes at least one optical path, and the optical path includes at least one on-chip optical switch 202. Accordingly, any two digital electrical chips 101 are capable of communicating with each other via at least one on-chip optical switch 202.

In an exemplary embodiment, the semiconductor device further comprises a substrate 104, and the photonic chip 100 is mounted on the substrate 104. The photonic chip 100 includes the photonic integrated circuit sub-chips according to any of the foregoing embodiments, such that the on-chip optical switching network described above is formed on the photonic chip 100. The four analog electrical chips 102 are respectively mounted at communication node locations on the photonic chip 100. As shown in FIG. 7, the analog electrical chips 102 are mounted above locations of the modulators or modulator arrays and the detectors or detector arrays and are communicatively connected thereto. The four digital electrical chips 101 are arranged around the photonic chip 100 and mounted on the substrate 104. A digital electrical chip 101 is mounted on the substrate 104 in proximity to each analog electrical chip 102, and each digital electrical chip 101 may be interconnected with its corresponding analog electrical chip 102 via an ultra-short-reach SerDes interface or a parallel interface.

Information transmission in the semiconductor device will now be described with reference to FIGS. 1 to 8. Light generated by a laser module 300 is coupled into the photonic chip 100 via a fiber array 301 and an optical input coupler 405. The coupled light is transmitted to the modulators 200 via a first-type optical waveguide 409 (or further via an optical power splitter 404) and second-type optical waveguides 400 connected to the modulators 200.

At a transmitting end, low-speed parallel signals (i.e., digital information) generated by a digital electrical chip 101 are converted into high-speed serial signals via a SerDes interface or a parallel interface. The high-speed serial signals are transmitted to a corresponding analog electrical chip 102 via wiring structures (for example, metal traces) formed on a substrate 104 and through-silicon vias (TSVs) 501 of the photonic chip 100. The analog electrical chip 102 generates electrical signals for optical modulation based on the received high-speed serial signals. The modulator 200 modulates the coupled light according to the electrical signals from the analog electrical chip 102 to generate modulated optical signals, thereby loading information carried by the electrical signals onto the modulated optical signals.

The modulated optical signals output from the modulator 200 are transmitted to an input port of a corresponding on-chip optical switch 202 via second-type optical waveguides 400 and first-type optical waveguides 401. Under control of an optical switching control analog electrical chip 103, the on-chip optical switch 202 determines an output port and reconfigures the optical path. The modulated optical signals are output from the determined output port of the on-chip optical switch 202 and are transmitted to a detector 201 at a receiving end via first-type optical waveguides 401 and second-type optical waveguides 400 that are optically coupled to the output port.

In some embodiments, the first-type optical waveguides 401 comprise silicon nitride waveguides, and the on-chip optical switch 202 comprises a silicon photonic switch. Input ports and output ports of the on-chip optical switch 202 are silicon waveguides, i.e., second-type optical waveguides 400. Accordingly, the first-type optical waveguides 401 are coupled to the input ports and output ports of the on-chip optical switch 202 via evanescent-wave couplers. The on-chip optical switch 202 is formed during fabrication of the photonic integrated circuit sub-chips and is compatible with other silicon photonic processes, thereby simplifying the fabrication process.

The detector 201 converts the received modulated optical signals into analog electrical signals via photonic-electronic conversion and transmits the analog electrical signals to a corresponding analog electrical chip 102 at the receiving end. The receiving-end analog electrical chip 102 processes the received electrical signals and transmits processed signals to a SerDes interface or a parallel interface of a corresponding digital electrical chip 101 at the receiving end via the TSVs 501 of the photonic chip 100 and wiring structures (for example, metal traces) on the substrate 104. The SerDes interface or parallel interface converts the serial signals into parallel signals, thereby enabling communication between the transmitting digital electrical chip and the receiving digital electrical chip.

In some embodiments, four digital electrical chips 101 are configured to transmit, receive, and process data in parallel via two on-chip optical switches 202. Accordingly, compared with conventional technologies, the system bandwidth of the semiconductor device of the present invention can be significantly improved.

In the exemplary embodiments illustrated in FIGS. 1 to 8, a first digital electrical chip is capable of communicating with a second digital electrical chip via one of the on-chip optical switches. The first digital electrical chip may also communicate with the second digital electrical chip via two on-chip optical switches simultaneously. Further, the first digital electrical chip may communicate with the second digital electrical chip via one on-chip optical switch while simultaneously communicating with a third digital electrical chip via another on-chip optical switch.

As described above, the present invention employs a photonic chip 100, formed by waveguide stitching of a plurality of photonic integrated circuit sub-chips fabricated using a full-reticle mask, as an interposer for integrating a plurality of analog electrical chips 102. The analog electrical chips 102 are connected to a plurality of digital electrical chips 101 disposed around the photonic chip 100 via SerDes interfaces or parallel interfaces. Information from different analog electrical chips is loaded (for example, modulated) onto optical signals, which then propagate at high speed through the on-chip all-optical switching network of the photonic chip 100. Data scheduling and switching are performed by central on-chip optical switches, thereby enabling information interconnection among different analog electrical chips. Accordingly, different digital electrical chips are interconnected as an integrated system via electronic-photonic conversion, photonic-electronic conversion, and optical interconnection.

In some embodiments, by integrating modulator arrays and detector arrays beneath different analog electrical chips, a large amount of information can be transmitted between chips without being constrained by power consumption or bandwidth density. By appropriately arranging positions of modulators or modulator arrays, detectors or detector arrays, on-chip optical switches, and corresponding analog electrical chips, effective bandwidth of the digital electrical chips can be increased, thereby improving overall system utilization.

It should be noted that the present invention does not limit a number of photonic integrated circuit sub-chips having on-chip optical switches on the photonic chip 100. The photonic integrated circuit sub-chips (and corresponding on-chip optical switches) described in the exemplary embodiments may be expanded according to application requirements to enable communication among a greater number of digital electrical chips, thereby increasing system bandwidth and computing capability.

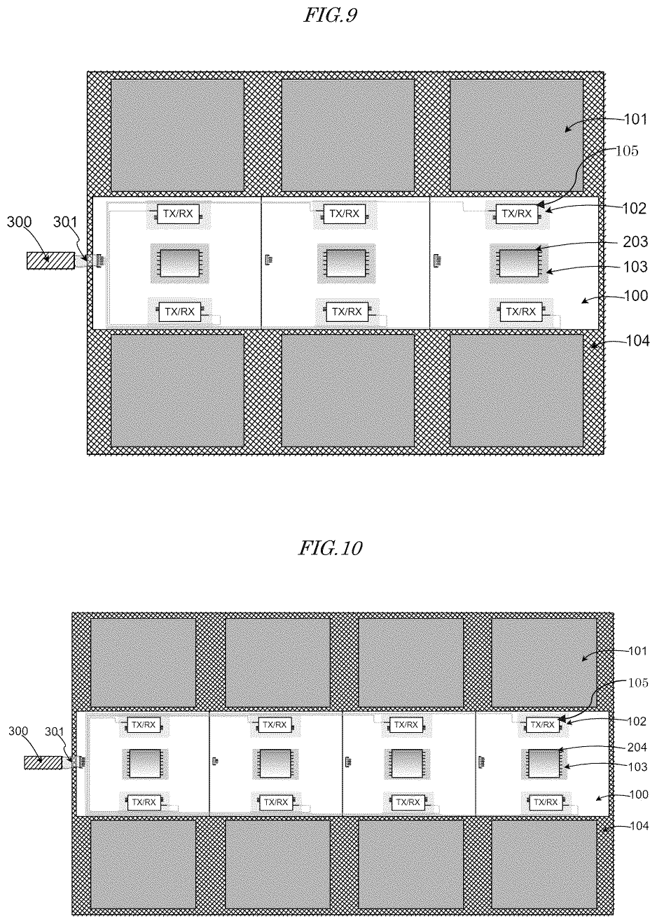

As shown in FIG. 9, in another embodiment, three photonic integrated circuit sub-chips are formed on the photonic chip 100 and arranged side by side. Each photonic integrated circuit sub-chip is provided with one 6×6 on-chip optical switch 203 and two analog electrical chips 102. The 6×6 on-chip optical switch 203 comprises thirty-six optical switching units arranged in a 6×6 matrix. By controlling an output port of each optical switching unit, arbitrary routing configurations between six-channel inputs and six-channel outputs can be implemented, and insertion loss of each optical path is independent of the routing path.

Accordingly, six analog electrical chips 102, three 6×6 on-chip optical switches 203, and corresponding optical switching control analog electrical chips 103 are disposed on the photonic chip 100. Corresponding to the analog electrical chips 102, six photonic transceiver devices (TX/RX) 105 are formed on the photonic chip 100, and six digital electrical chips 101 are disposed on the substrate 104 outside the photonic chip 100. In some embodiments, each photonic transceiver device 105 comprises a modulator or modulator array and a detector or detector array. For example, a photonic transmitter (TX) comprises a modulator or modulator array, and a photonic receiver (RX) comprises a detector or detector array.

Although not shown, optical waveguide routing in the photonic chip 100 is similar to that described in the foregoing embodiments. Specifically, six input ports of each 6×6 on-chip optical switch 203 are respectively optically connected to photonic transmitters of the six photonic transceiver devices via six first-type optical waveguides, and six output ports are respectively optically connected to photonic receivers of the six photonic transceiver devices via another six first-type optical waveguides. Accordingly, six digital electrical chips 101 of the semiconductor device are capable of communicating with one another via an on-chip optical switching network formed by any one of the 6×6 on-chip optical switches 203. Since the six digital electrical chips 101 may be configured to transmit, receive, and process data in parallel, system bandwidth and computing capability can be substantially improved.

As shown in FIG. 10, in yet another embodiment, four photonic integrated circuit sub-chips are arranged side by side on the photonic chip 100. Each photonic integrated circuit sub-chip is provided with one 8×8 on-chip optical switch 204 and two analog electrical chips 102, such that eight digital electrical chips 101 are disposed on the substrate 104 outside the photonic chip 100. Other structures of the semiconductor device shown in FIG. 10 are similar to corresponding structures shown in FIG. 8. In the semiconductor device illustrated in FIG. 10, the eight digital electrical chips 101 are capable of communicating with one another via an on-chip optical switching network formed by any one of the 8×8 on-chip optical switches 204. The 8×8 on-chip optical switch 204 comprises sixty-four optical switching units arranged in an 8×8 matrix. By controlling an output port of each optical switching unit, arbitrary routing configurations between eight-channel inputs and eight-channel outputs can be implemented, and insertion loss of each optical path is independent of the routing path.

It should be understood that the present invention is not limited thereto. Depending on a scale of an optoelectronic computing system, a photonic chip including a greater number of photonic integrated circuit sub-chips having on-chip optical switches may be employed to enable communication among a greater number of digital electrical chips. Through lateral expansion of on-chip optical switches (for example, providing two or more on-chip optical switches on each photonic integrated circuit sub-chip), multiple digital electrical chips may simultaneously perform parallel information processing, thereby better satisfying requirements of artificial intelligence algorithms for computing capability and bandwidth. Compared with existing artificial intelligence computing systems, an optoelectronic computing system employing the on-chip all-optical switching network apparatus or semiconductor device of the present invention can integrate a larger number of computing chips and memory chips, while ensuring information interconnection via optical interconnections, thereby achieving higher system energy efficiency.

Furthermore, embodiments of the present invention provide a method for manufacturing the on-chip all-optical switching network apparatus according to any one of the foregoing embodiments, the method comprising:
providing a photonic chip in which at least two photonic integrated circuit sub-chips are formed, adjacent photonic integrated circuit sub-chips being optically interconnected with each other; and
providing at least two optical-switching control analog electrical chips and respectively disposing the optical-switching control analog electrical chips on the at least two photonic integrated circuit sub-chips;
wherein each photonic integrated circuit sub-chip comprises at least one on-chip optical switch, at least two communication nodes configured to communicate with external devices, and a plurality of first-type optical waveguides configured to connect the at least one on-chip optical switch with the at least two communication nodes, and wherein each on-chip optical switch is arranged in a one-to-one correspondence with a respective one of the at least two optical switching control analog electrical chips, and wherein any two of the communication nodes communicate with each other via the at least one on-chip optical switch.

On each photonic integrated circuit sub-chip, the optical-switching control analog electrical chip is disposed above the on-chip optical switch so as to control the on-chip optical switch.

In some embodiments, the photonic integrated circuit sub-chips are fabricated by exposure using a full-reticle mask. The structures of the photonic chip and the photonic integrated circuit sub-chips are as described above and will not be repeated herein.

Additionally, embodiments of the present invention further provide a method for manufacturing the semiconductor device according to any one of the foregoing embodiments, the method comprising:
providing the on-chip all-optical switching network apparatus according to any one of the foregoing embodiments, the structure of which is as described above and will not be repeated herein;
providing a plurality of analog electrical chips and configuring the plurality of analog electrical chips such that any two of the analog electrical chips communicate with each other via at least one on-chip optical switch in the on-chip all-optical switching network apparatus; and
providing a plurality of digital electrical chips and electrically connecting each digital electrical chip to a corresponding analog electrical chip such that any two of the digital electrical chips communicate with each other via at least two analog electrical chips and the at least one on-chip optical switch.

In some embodiments, the method for manufacturing the semiconductor device further comprises:
providing a substrate;
mounting the photonic chip on the substrate; and
mounting the plurality of analog electrical chips respectively on corresponding photonic integrated circuit sub-chips of the photonic chip, and respectively mounting the plurality of digital electrical chips corresponding to the analog electrical chips on the substrate.

In some embodiments, providing the analog electrical chips and the digital electrical chips separately not only enables optimization of the respective chip performances using different process technologies, but also addresses the slow product iteration cycle of analog electrical chips, and further improves the overall yield of the system.

In some embodiments, the on-chip optical switching network is formed on the photonic chip by stitching full-reticle photonic integrated circuit sub-chips. Except for exposure masks used for optical couplers connecting an input laser to silicon nitride waveguides of the communication nodes, exposure masks for other components on the photonic integrated circuit sub-chips are identical, thereby reducing chip tape-out costs.

Those skilled in the art should understand that the foregoing descriptions are merely exemplary embodiments of the present invention and are not intended to limit the scope of protection sought by this application. Any equivalent modifications or variations made in accordance with the embodiments of the present invention shall fall within the scope of the claims of this application.

For example, in optional embodiments, the photonic chip is bonded to an interposer, and the interposer is mounted on the substrate. The interposer may be made of materials such as silicon, glass, or ceramic, and primarily serves a supporting function to reduce warpage or fragmentation of the photonic chip. In other optional embodiments, the photonic chip including the photonic integrated circuit sub-chips may be disposed on an upper surface of the interposer, while the digital electrical chips may be disposed on a lower surface of the interposer. In further optional embodiments, the analog electrical chips may alternatively be disposed on the substrate and electrically connected to the photonic integrated circuit sub-chips through metal interconnects. Those skilled in the art should understand that such variations also fall within the scope of protection of the present application.

1. An on-chip all-optical switching network apparatus, comprising:
a photonic chip in which at least two photonic integrated circuit (PIC) sub-chips are formed, wherein adjacent photonic integrated circuit sub-chips are optically interconnected with each other; and
at least two optical switching control analog electrical chips respectively disposed on the at least two photonic integrated circuit sub-chips;
wherein each photonic integrated circuit sub-chip comprises at least one on-chip optical switch, at least two communication nodes configured to communicate with external devices, and a plurality of first-type optical waveguides configured to connect the at least one on-chip optical switch with the communication nodes, wherein each on-chip optical switch is arranged in a one-to-one correspondence with a respective one of the at least two optical switching control analog electrical chips; and
wherein, on the photonic chip, any two of the communication nodes are configured to communicate with each other via the at least one on-chip optical switch.

2. The apparatus according to claim 1, wherein, on each photonic integrated circuit sub-chip, the optical switching control analog electrical chip is disposed above the on-chip optical switch so as to control the on-chip optical switch.

3. The apparatus according to claim 1, wherein, each communication node comprises at least two electronic-photonic conversion units and at least two photonic-electronic conversion units;
wherein the at least two electronic-photonic conversion units are optically connected to at least two on-chip optical switches via respective first-type optical waveguides; and
wherein the at least two photonic-electronic conversion units are optically connected to output ports of the at least two on-chip optical switches via respective first-type optical waveguides.

4. The apparatus according to claim 3, wherein, in each communication node, a number of the electronic-photonic conversion units is equal to that of the photonic-electronic conversion units, and each is equal to a total number of the on-chip optical switches on the photonic chip.

5. The apparatus according to claim 3, wherein, each on-chip optical switch comprises a plurality of input ports and a plurality of output ports,
and wherein the number of the input ports and the number of the output ports of each on-chip optical switch are equal to a total number of the communication nodes on the photonic chip.

6. The apparatus according to claim 5, wherein, the plurality of input ports of each on-chip optical switch are respectively optically connected to at least one electronic-photonic conversion unit in each communication node via different first-type optical waveguides, and
wherein the plurality of output ports of each on-chip optical switch are respectively optically connected to at least one photonic-electronic conversion unit in each communication node via different first-type optical waveguides.

7. The apparatus according to claim 3, wherein, each electronic-photonic conversion unit comprises a modulator, and/or each photonic-electronic conversion unit comprises a detector.

8-9. (canceled)

10. The apparatus according to claim 7, wherein, the modulator comprises a micro-ring modulator, a Mach-Zehnder modulator, or an electro-absorption modulator;
wherein, the detector comprises a micro-ring detector or a photodiode.

11. (canceled)

12. The apparatus according to claim 7, wherein, each photonic integrated circuit sub-chip further comprises:
an optical input coupler and an optical power splitter, wherein:
the optical input coupler on one of the photonic integrated circuit sub-chips is configured to couple light from an off-chip light source into the photonic chip; and
the optical power splitter is optically connected to the optical input coupler via another first-type optical waveguide and is configured to split light from the optical input coupler into a plurality of optical outputs having substantially identical power, the plurality of optical outputs being transmitted to the respective modulators.

13. The apparatus according to claim 12, wherein in the photonic chip, first-type optical waveguides of two adjacent photonic integrated circuit sub-chips are optically interconnected.

14. The apparatus according to claim 13, wherein first-type optical waveguides facing each other at a junction of two adjacent photonic integrated circuit sub-chips are configured such that the waveguide cross section gradually increases from one photonic integrated circuit sub-chip toward the other photonic integrated circuit sub-chip.

15. The apparatus according to claim 12, wherein each photonic integrated circuit sub-chip further comprises second-type optical waveguides disposed in a different layer from the first-type optical waveguides;
wherein one or more of the at least one on-chip optical switch, the at least two electronic-photonic conversion units, the at least two photonic-electronic conversion units, the optical input coupler, and the optical power splitter are optically connected to corresponding first-type optical waveguides via respective second-type optical waveguides; and
wherein the second-type optical waveguides are optically coupled to the first-type optical waveguides via evanescent-wave couplers.

16. The apparatus according to claim 15, wherein, the first-type optical waveguides comprise silicon nitride waveguides, and the second-type optical waveguides comprise silicon waveguides.

17. The apparatus according to claim 1, wherein, each on-chip optical switch comprises a silicon photonic switch including a plurality of optical switching units;
and wherein each optical switching control analog electrical chip is configured to control the plurality of optical switching units to perform data scheduling and switching in the on-chip all-optical switching network.

18. (canceled)

19. The apparatus according to claim 17, wherein, the at least one on-chip optical switch and the at least two communication nodes are disposed in the same layer.

20. The apparatus according to claim 1, wherein the photonic integrated circuit sub-chips are fabricated by exposure using a full-reticle mask.

21. A semiconductor device, comprising:
the on-chip all-optical switching network apparatus according to claim 1;
a plurality of analog electrical chips connected to the on-chip all-optical switching network apparatus and configured such that any two of the analog electrical chips communicate with each other via at least one on-chip optical switch of the on-chip all-optical switching network apparatus; and
a plurality of digital electrical chips, each digital electrical chip being electrically connected to a respective analog electrical chip, such that any two of the digital electrical chips communicate with each other via at least two of the analog electrical chips and the at least one on-chip optical switch.

22. The semiconductor device according to claim 21, further comprising a substrate,
wherein the photonic chip is mounted on the substrate; and
wherein the plurality of analog electrical chips are respectively mounted on corresponding photonic integrated circuit sub-chips of the photonic chip, and the digital electrical chips corresponding to the respective analog electrical chips are mounted on the substrate.

23. The semiconductor device according to claim 22, wherein, on each photonic integrated circuit sub-chip, the analog electrical chips are arranged in a one-to-one correspondence with the communication nodes, and each analog electrical chip is disposed above the corresponding communication node.

24. A method for manufacturing the on-chip all-optical switching network apparatus according to claim 1, comprising:
providing a photonic chip in which at least two photonic integrated circuit sub-chips are formed, adjacent photonic integrated circuit sub-chips being optically interconnected with each other; and
providing at least two optical switching control analog electrical chips and respectively disposing the optical switching control analog electrical chips on the at least two photonic integrated circuit sub-chips;
wherein each photonic integrated circuit sub-chip comprises at least one on-chip optical switch, at least two communication nodes configured to communicate with external devices, and a plurality of first-type optical waveguides configured to connect the at least one on-chip optical switch with the at least two communication nodes, and wherein each on-chip optical switch is arranged in a one-to-one correspondence with a respective one of the at least two optical switching control analog electrical chips; and
wherein any two of the communication nodes are configured to communicate with each other via the at least one on-chip optical switch.

25-26. (canceled)
